(19) United States
(12) Patent Application Publication
(10) Pub. No.: US 2026/0052984 A1
(43) Pub. Date: Feb. 19, 2026

(54) SEMICONDUCTOR MODULE HAVING AT LEAST A FIRST SEMICONDUCTOR ASSEMBLY, A SECOND SEMICONDUCTOR ASSEMBLY AND A COMMON HEAT SINK

(71) Applicant: Siemens Aktiengesellschaft, 80333 München (DE)

(72) Inventors: Matthias NÄHRIG, Hemhofen (DE); JENS SCHMENGER, Forchheim (DE)

(73) Assignee: Siemens Aktiengesellschaft, 80333 München (DE)

(21) Appl. No.: 19/100,446

(22) PCT Filed: Jul. 26, 2023
(86) PCT No.: PCT/EP2023/070729

§ 371 Date: Jan. 31, 2025

(30) Foreign Application Priority Data
Aug. 2, 2022 (EP) 22188328.3

(51) Int. Cl. H01L 23/367; H01L 23/373; H01L 25/11

(52) U.S. Cl. CPC H01L 23/3672; H01L 23/3735; H01L 25/115

(57) ABSTRACT

A semiconductor module includes a heat sink configured to conduct a cooling fluid in a cooling-fluid flow direction. A first semiconductor assembly is arranged on a surface of the heat sink. The first semiconductor assembly includes a first substrate having a first dielectric material layer, and a first semiconductor element connected to the first substrate. A second semiconductor assembly is arranged on the surface of the heat sink and closest to a downstream end of the heat sink. The second semiconductor assembly includes a second substrate having a second dielectric material layer, and a second semiconductor element connected to the second substrate. The second dielectric material layer has a thermal conductivity which is higher than a thermal conductivity of the first dielectric material layer.

### DESCRIPTION

The invention relates to a semiconductor module having at least a first semiconductor assembly, a second semiconductor assembly and a common heat sink.

The invention further relates to a power converter having at least one such power semiconductor module.

In addition, the invention relates to a method for producing such a semiconductor module.

The invention additionally relates to a computer program product, comprising commands, which, when the program is executed by a computer, cause it to simulate a behavior of such a semiconductor module.

In such power converters, semiconductor modules, in particular closed by a housing, are generally screwed to a heat sink, for example via a solid metal baseplate. A power converter is for example to be understood as a rectifier, an inverter, a converter or a DC-DC converter. The semiconductor elements used in the semiconductor modules include transistors, diodes, triacs or thyristors. The transistors are for example designed as insulated gate bipolar transistors (IGBTs), field effect transistors or bipolar transistors. The semiconductor elements are normally contacted on a substrate.

The published patent application WO 2022/002464 A1 describes a power module having at least two power units, which each comprise at least one power semiconductor and a substrate. In order to reduce the installation space required for the power module and to improve cooling, it is proposed that the respective at least one power semiconductor is connected, in particular in a material-bonded manner, to the respective substrate, wherein the substrates of the at least two power units are each directly connected in a material-bonded manner to a surface of a common heat sink.

The published patent application U.S. Pat. No. 10,014,238 B2 describes an electronic assembly that includes a thermal management system that can include a heat sink having electronic components mounted thereon. The electronic components can be mounted on the heat sink in a staggered pattern along a centerline substantially perpendicular to the direction of flow of a coolant.

Against this backdrop, it is an object of the present invention to specify a semiconductor module which has improved reliability.

This object is inventively achieved by a semiconductor module having at least a first semiconductor assembly, a second semiconductor assembly and a common heat sink, wherein the heat sink is configured such that a cooling fluid is conducted in a cooling-fluid flow direction, wherein the semiconductor assemblies are arranged on a surface of the heat sink, wherein the semiconductor assemblies each have a substrate, and on each of said substrates at least one semiconductor element is connected, in particular in a material-bonded manner, wherein the substrates each comprise a dielectric material layer, wherein a second dielectric material layer of the second semiconductor assembly differs, at least in respect of its thermal conductivity, from a first dielectric material layer of the first semiconductor assembly, wherein the second semiconductor assembly is arranged closest to a downstream end of the heat sink, wherein the second dielectric material layer has a higher thermal conductivity than the first dielectric material layer.

The object is further inventively achieved by a power converter having at least one such semiconductor module.

The object is additionally inventively achieved by a method for producing such a semiconductor module, wherein to produce the semiconductor assemblies at least one semiconductor element is in each case connected, in particular in a material-bonded manner, on a substrate, wherein in a further step the semiconductor assemblies are connected, in particular in a material-bonded manner, on the surface of the heat sink.

In addition, the object is inventively achieved by a computer program product, comprising commands, which when the program is executed by a computer cause it to simulate an, in particular thermal, mechanical and/or electrical, behavior of such a semiconductor module.

The advantages and preferred embodiments explained below in respect of the semiconductor module can be transferred analogously to the power converter, the method and the computer program product.

The invention is based on the consideration of improving the reliability of a semiconductor module by uniformly cooling semiconductor assemblies arranged on a surface of a common heat sink. The cooling is effected via a cooling fluid which is conducted in a cooling-fluid flow direction. The cooling fluid can be gaseous, for example air. Additionally or alternatively, liquid cooling fluids or phase-change cooling can also be used. The semiconductor assemblies each have a substrate on which at least one semiconductor element is connected. The semiconductor elements are for example connected to the respective substrate in a material-bonded manner, in particular by soldering, sintering or adhesion. The substrates of the semiconductor assemblies each comprise a dielectric material layer for producing an electrically insulating and thermally conductive connection of the respective semiconductor elements to the common heat sink. Such dielectric material layers can contain a ceramic material, among other things. In order to achieve a uniform cooling, a second dielectric material layer of the second semiconductor assembly differs, at least in respect of its thermal conductivity, from a first dielectric material layer of the first semiconductor assembly. For example, for the second semiconductor assembly, which e.g. has higher thermal losses than the first semiconductor assembly, a second dielectric material layer is used, which has a higher thermal conductivity than the first dielectric material layer. Thus uniform cooling is achieved even with different waste heat, which has a positive effect on the reliability of the semiconductor module and extends its service life.

A computer program product which comprises commands, which when the program is executed by a computer cause it to simulate an, in particular thermal, mechanical and or electrical, behavior of the semiconductor module can comprise a “digital twin” or be designed as such. Such a digital twin is for example shown in the published patent application US 2017/0286572 A1. The contents of the disclosure in US 2017/0286572 A1 are also included by reference in the present application. The “digital twin” is for example a digital representation of the components that are relevant to the operation of the semiconductor module,

The second semiconductor assembly is arranged closest to a downstream end of the heat sink, wherein the second dielectric material layer has a higher thermal conductivity than the first dielectric material layer. For example, the common heat sink is supplied with a cooling air flow on one side, e.g. via a fan, wherein the cooling air flow is conducted from an upstream end to a downstream end of the common heat sink. In particular, the second semiconductor assembly is arranged between the first semiconductor assembly and the downstream end of the common heat sink. Due to the thermal losses of the first semiconductor assembly, the cooling fluid heats up when it reaches the second semiconductor assembly. Due to the higher thermal conductivity of the second dielectric material layer, a more uniform cooling and thus a thermal optimization is achieved.

A further form of embodiment provides that the semiconductor module has at least a third semiconductor assembly, which is arranged between the first semiconductor assembly and the second semiconductor assembly, having a third substrate on which at least one semiconductor element is connected, in particular in a material-bonded manner, wherein the third substrate comprises a third dielectric material layer, wherein the third dielectric material layer differs, at least in respect of its thermal conductivity, from the first dielectric material layer and/or the second dielectric material layer. Among other things, the at least three semiconductor assemblies can each comprise a half-bridge for the realization of a three-phase power converter, in particular when there are more than three semiconductor assemblies in a multilevel power converter. Additionally or alternatively, semiconductor assemblies can be connected in parallel, enabling simple scaling or modularization of the semiconductor module.

A further form of embodiment provides that the second dielectric material layer has a higher thermal conductivity than the first dielectric material layer and/or the third dielectric material layer. Due to the higher thermal conductivity of the second dielectric material layer, which is arranged closest to the downstream end of the heat sink, a more uniform cooling and thus a thermal optimization is achieved.

A further form of embodiment provides that the semiconductor assemblies are arranged in a staggered pattern along an axis on a surface of the heat sink, wherein the cooling-fluid flow direction extends substantially along the axis. The axis can be referred to as the flow axis, among other things, wherein the cooling-fluid flow direction runs substantially in parallel to the flow axis. For example, the semiconductor assemblies are distributed alternately staggered, in particular with variable spacings, along the flow axis. Alternately staggered here means that the semiconductor assemblies are shifted alternately to the left and right in relation to the axis. In this way a more uniform cooling of the semiconductor assemblies is achieved.

A further form of embodiment provides that a substrate surface of the semiconductor assembly arranged closest to the downstream end of the heat sink is larger, In particular at least 50% larger, than a substrate surface of a further semiconductor assembly arranged on the surface of the heat sink. In this way an Improved heat splay can be achieved, as a result of which a more uniform cooling is additionally achieved, which has a positive effect on the reliability of the semiconductor module and extends its service life.

A further form of embodiment provides that a semiconductor assembly arranged closest to the downstream end of the heat sink is configured as at least part of an inverter. In particular, the semiconductor assembly arranged at the downstream end of the heat sink has a dielectric material layer with a higher thermal conductivity. Such inverters comprise switchable semiconductor elements, in particular transistors, such as IGBTs, while a rectifier, which can form a converter with an inverter, can be produced with non-switchable semiconductor elements, such as diodes. Hence in such an inverter a larger temperature swing can occur during operation in the current flow, wherein a higher thermal conductivity of the dielectric material layer significantly reduces the temperature swing, which has a positive effect on the service life of the semiconductor module.

A further form of embodiment provides that the substrates of the semiconductor assemblies are each directly connected in a material-bonded manner to the surface of the common heat sink via a connecting layer. A direct material-bonded connection is to be understood as a direct connection which includes connection means for producing the material-bonded connection such as adhesive, a solder alloy, sintering paste, etc., but excludes an additional connecting element such as an additional conductor, a bonding wire, a spacer, a base plate, thermal paste, etc. By omitting such an additional connecting element, an improved thermal connection of the semiconductor elements is achieved, so that improved cooling takes place. In addition, installation space is saved due to the direct material-bonded connection.

A further form of embodiment provides that at least the first dielectric material layer of the first substrate contains aluminum oxide and at least the second dielectric material layer of the second substrate contains aluminum nitride. While aluminum oxide is less expensive, aluminum nitride makes less of a contribution to the temperature swing, so that the overall temperature swing is reduced. For example, aluminum oxide contributes 40 K to the temperature swing, while aluminum nitride contributes only 36 K. By using the more expensive aluminum nitride in the semiconductor assembly arranged at the downstream end of the heat sink, a more uniform cooling is achieved and thus the service life of the semiconductor module is improved.

A further form of embodiment provides that a first connecting layer for connecting the first substrate is thinner than a second connecting layer for connecting the second substrate. For example, the second connecting layer is 1.2-times thicker than the first connecting layer. In particular, the coefficient of expansion of aluminum nitride differs more from that of a metal surface of the heat sink, which e.g. contains copper or aluminum, than the coefficient of expansion of aluminum oxide. A thicker connecting layer absorbs more stresses caused by unequal coefficients of expansion and thus buffers stress better between the respective dielectric material layer and the metal heat sink. Thus a thicker second connecting layer prevents deflection of the heat sink due to unequal coefficients of expansion.

A further form of embodiment provides that a first connecting layer for connecting the first substrate is made of a first alloy and a second connecting layer for connecting the second substrate is made of a second alloy, wherein the first alloy differs from the second alloy in respect of its composition. For example, the second connecting layer for connecting the second substrate is exposed to a higher thermal load, so that a less expensive and less well performing alloy is sufficient for the first connecting layer for connecting the first substrate.

A further form of embodiment provides that the second alloy has a higher mass fraction of antimony than the first alloy. For example, an inexpensive SAC (tin/silver/copper) solder is used for the first alloy, while a better performing tin-antimony alloy is used for the second alloy for connecting the second substrate, which is exposed to a higher thermal load. Thus an improved cost position is achieved with high reliability of the semiconductor module.

A further form of embodiment provides that the substrates of the semiconductor assemblies each have a thickness of between 25 μm and 400 μm, in particular 50 μm and 250 μm. Such a thickness represents a compromise in respect of thermal optimization and deflection of the heat sink.

The invention is described and explained in greater detail below on the basis of the exemplary embodiments shown in the figures.

It is shown in:

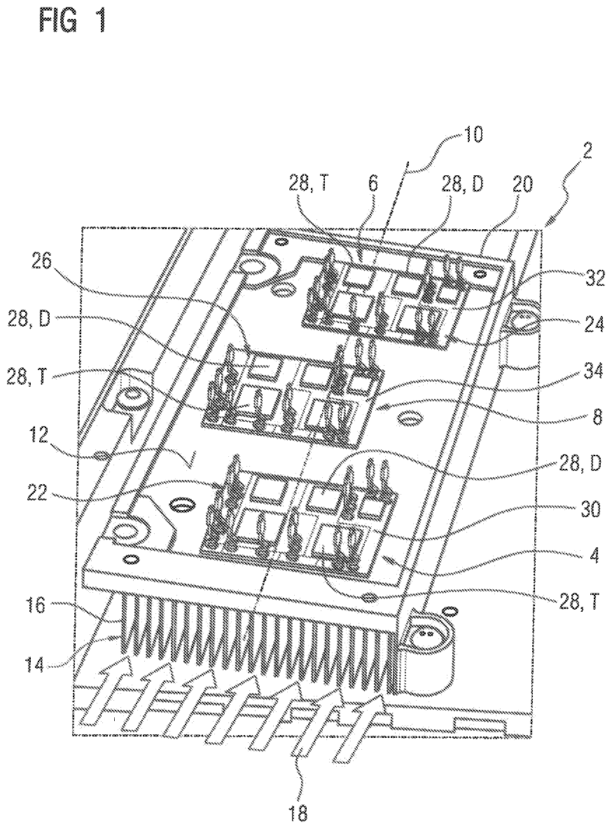

FIG. 1 a schematic perspective representation of a first form of embodiment of a semiconductor module,

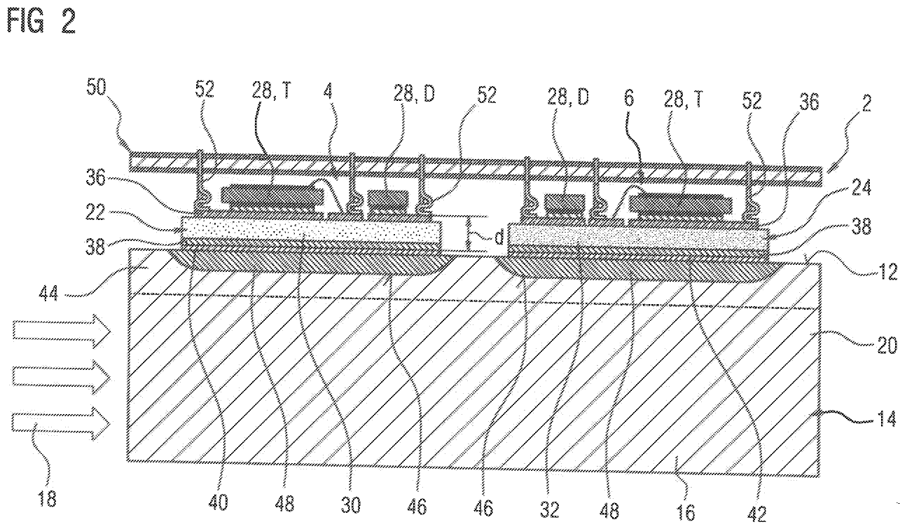

FIG. 2 a schematic cross-sectional representation of a second form of embodiment of a semiconductor module,

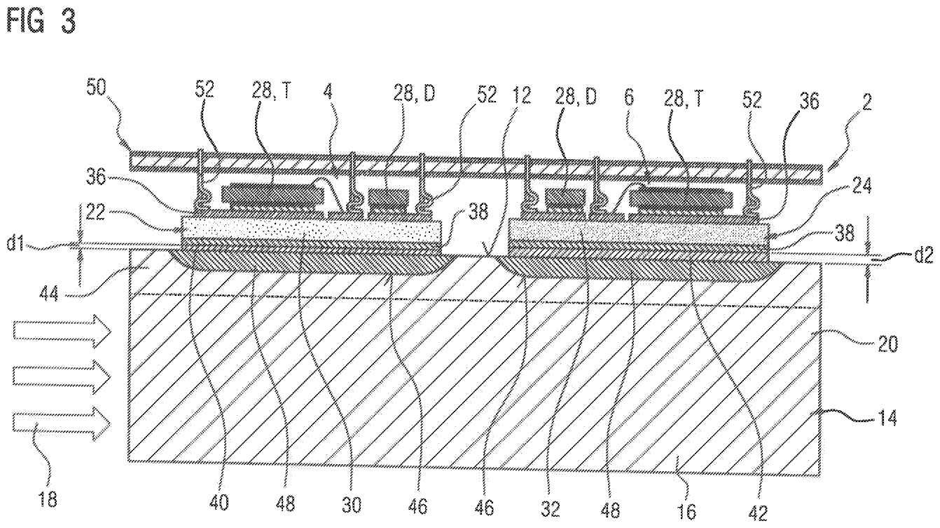

FIG. 3 a schematic cross-sectional representation of a third form of embodiment of a semiconductor module,

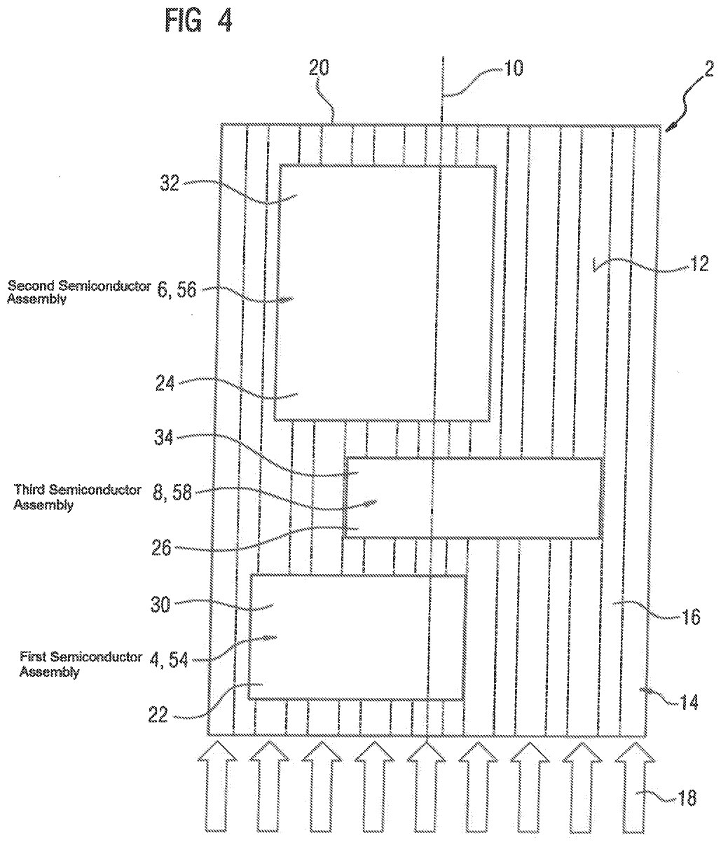

FIG. 4 a schematic representation of a fourth embodiment of a semiconductor module in a plan view,

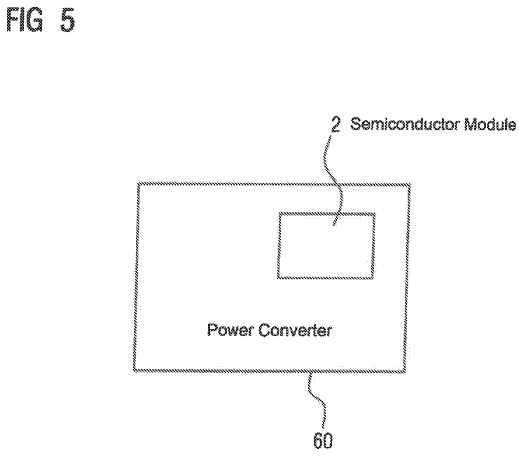

FIG. 5 a schematic representation of a power converter having a semiconductor module.

The exemplary embodiments described below are preferred forms of embodiment of the invention. In the case of the exemplary embodiments, the described components of the forms of embodiment each represent individual features of the invention which are to be considered independently of one another and which also develop the invention Independently of one another and are thus also to be regarded as a component of the invention individually or in a combination other than that shown. Furthermore, the described forms of embodiment can also be supplemented by further features of the invention that have already been described.

The same reference characters have the same meaning in the various figures.

FIG. 1 shows a schematic perspective representation of a first form of embodiment of a semiconductor module 2, which comprises a first semiconductor assembly 4, a second semiconductor assembly 6 and a third semiconductor assembly 8, wherein the semiconductor assemblies 4, 6, 8 are mounted in a staggered pattern along an axis 10 on a surface 12 of a common heat sink 14. The common heat sink 14 is configured by cooling ribs 16, which are designed as cooling fins, so that a gaseous cooling fluid flows in a coolant flow direction 18 along the cooling fins, wherein the cooling-fluid flow direction 18 extends substantially in parallel to the axis 10. The semiconductor module 2 is thus cooled on one side.

The second semiconductor assembly 6 is arranged closest to a downstream end 20 of the common heat sink 14. Additionally, the semiconductor assemblies 4, 6, 8 each comprise a substrate 22, 24, 26, and on each of said substrates 22, 24, 26 semiconductor elements 28 are connected, in particular in a material-bonded manner. By way of example, the semiconductor elements 28 are designed as transistors T and as diodes D connected in anti-parallel. In particular, the transistors T are designed as vertical power transistors, for example as insulated gate bipolar transistors (IGBTs). The material-bonded connection of the semiconductor elements 28 to the respective substrate 22, 24, 26 can be produced by soldering, sintering or adhesion, etc.

The substrates 22, 24, 26 each comprise a dielectric material layer 30, 32, 34, in particular metallized on both sides, via which the respective semiconductor elements 28 are connected in an electrically insulating and thermally conductive manner to the common heat sink 14, By way of example, a second dielectric material layer 32 of the second semiconductor assembly 6 differs at least from a first dielectric material layer 30 of the first semiconductor assembly 4 in respect of its thermal conductivity. In addition, a third dielectric material layer 34 of the third semiconductor assembly 8 can differ from the first dielectric material layer 30 and/or the second dielectric material layer 6 in respect of its thermal conductivity.

For example, the cooling fluid flowing in the coolant flow direction 18 can heat up due to the heat losses arising in the semiconductor elements 28 of the first semiconductor assembly 4 and third semiconductor assembly 8, so that a higher thermal conductivity of the second dielectric material layer 32 results in a more uniform cooling of the semiconductor assemblies 4, 6, 8. For example, the first dielectric material layer 30 of the first substrate 22 and the third dielectric material layer 34 of the third substrate 26 are made of aluminum oxide, while the second dielectric material layer 32, situated closest to the downstream end 20 of the common heat sink 14, of the second substrate 24 is made of aluminum nitride, which has a higher thermal conductivity than aluminum oxide. In this way temperature swings during operation of the semiconductor module 2, for example in the region of the second semiconductor assembly 4, are reduced, which has a positive effect on the service life of the semiconductor module 2.

FIG. 2 shows a schematic cross-sectional representation of a second form of embodiment of a semiconductor module 2, which by way of example comprises two semiconductor assemblies 4, 6, wherein the second semiconductor assembly 6 is arranged closest to the downstream end 20 of the heat sink 14. The substrates 22, 24 each have a thickness d of between 25 μm and 400 μm, in particular 50 μm and 250 μm. Furthermore, they are each formed from a dielectric material layer 30, 32 which is metallized on both sides and contains a ceramic material. The first dielectric material layer 30 of the first substrate 22 is made of aluminum oxide, while the second dielectric material layer 32 of the second substrate 24 situated closest to the downstream end 20 of the common heat sink 14 is made of aluminum nitride, which has a higher thermal conductivity than aluminum oxide. The semiconductor elements 28 are connected in a material-bonded manner to the respective substrate 22, 24 via a first metallization 36. In addition, the substrates 22, 24 of the semiconductor assemblies 4, 6 each have a second metallization 38 on a side facing away from the semiconductor elements 28, which are directly connected in a material-bonded manner to the surface 12 of the common heat sink 14 via a connecting layer 40, 42. The semiconductor elements 28 are thus connected to the common heat sink 14 in an electrically insulating and thermally conductive manner via respective dielectric material layers 30, 32. The direct material-bonded connection via the respective connecting layer 40, 42 can be produced by soldering or sintering, etc., but no additional connecting elements such as metal blocks, metal sheets or heat-conducting paste are used. The first connecting layer 40 for connecting the first substrate 22 is made of a first alloy and the second connecting layer 42 for connecting the second substrate 24 is made of a second alloy, wherein the first alloy differs from the second alloy in respect of its composition. In particular, the second alloy contains a higher mass fraction of antimony than the first alloy. For example, the first alloy is an inexpensive SAC (tin/silver/copper) solder, while the second alloy is a tin-antimony alloy. The second dielectric material layer 32 of the second substrate 24, which is made of aluminum nitride, causes a stronger deflection of the heat sink 14 than the first dielectric material layer 30 of the first substrate 22, which is made of aluminum oxide, because of its coefficient of expansion, which is different in relation to the metal heat sink 14, this being at least partially compensated for by the better performing second alloy.

The heat sink 14 is made of a first metallic material 44, for example aluminum or an aluminum alloy. Cavities 46 are introduced 46 on its surface 12, and are filled with a second metallic material 48 which has a higher thermal conductivity than the first metallic material. For example, the second metallic material 48 contains copper. A cavity 46 filled with the second metallic material 48 is assigned to the semiconductor assemblies 4,6 in each case, wherein the second metallic material 48 is substantially flush with the surface 12 of the heat sink 14. The connecting layers 40, 42 are each fully connected to the second metallic material 48 of the cavities 46. In particular, the second metallic material 48 is introduced into the cavities 46 using an additive method, for example using cold gas spraying. A dedicated sensor, in particular a temperature sensor, can in each case be assigned to the semiconductor assemblies 4,6, in order to monitor the temperature of the semiconductor elements 28.

A power board 50 arranged running substantially in parallel to the surface 12 of the heat sink 14 is connected to the semiconductor assemblies 4, 6 via freely positionable contacts 52, wherein the freely positionable contacts 52 are connected in a material-bonded manner to the first metallizations 36 of the respective substrates 22, 24 of the semiconductor assemblies 4, 6. In this context, a power board 50 is to be understood as a circuit board which is designed e.g. as in particular a multilayer printed circuit board (PCB). The circuit board for example contains an interface to the power units, a driver circuit, a control circuit, and/or capacitors. In this context, a freely positionable contact 52 is to be understood as, among other things, a pin which can be freely arranged on a substrate 22, 24 due to its structural properties. Such structural properties are for example a base which allows the pin to be freely and stably arranged on the substrate without a housing or other stabilizing means, for example by a material-bonded connection to the substrate, and/or a wobble circle which facilitates the finding of a hole in the power board 50 and ensures greater stability and robustness, e.g. in the event of thermal expansion during operation. The freely positionable contacts 52 have an elastically yielding section and are for example connected to the power board 50 with a press-fit connection. The further design of the semiconductor module 2 in FIG. 2 corresponds to the design in FIG. 1.

FIG. 3 shows a schematic cross-sectional representation of a third form of embodiment of a semiconductor module 2. The first dielectric material layer 30 of the first substrate 22 is made of aluminum oxide, while the second dielectric material layer 32 of the second substrate 24 situated closest to the downstream end 20 of the common heat sink 14 is made of aluminum nitride. The first connecting layer 40 for connecting the first substrate 22 has a first thickness d1, while the second connecting layer 42 for connecting the second substrate 24 has a second thickness d2, wherein the second thickness d2 of the second connecting layer 42 is greater than the first thickness d1 of the first connecting layer 40. In particular, the second thickness d2 is 1.2-times or 20% greater than the first thickness d1, Because of its different coefficient of expansion in relation to the metal heat sink 14, the second dielectric material layer 32 made of aluminum nitride ensures a greater deflection of the heat sink 14 than the first dielectric material layer 30 made of aluminum oxide, which is compensated for at least partially by the thicker second connecting layer 42. The thicker second connecting layer thus acts more strongly as a stress-buffering layer between the respective dielectric material layer 30, 32 and the metal heat sink 14. The further design of the semiconductor module 2 in FIG. 3 corresponds to the design in FIG. 2.

FIG. 4 shows a schematic representation of a fourth embodiment of a semiconductor module 2 in a plan view, which by way of example has three semiconductor assemblies 4, 6, 8, wherein the semiconductor assemblies 4, 6, 8 are arranged in a staggered pattern along an axis 10 on the surface 12 of the heat sink 14. The second semiconductor assembly 6 is arranged closest to the downstream end 20 of the heat sink 14. With regard to the axis 10, the third semiconductor assembly 8 is arranged between the first semiconductor assembly 4 and the second semiconductor assembly 6. The first semiconductor assembly 4 is configured as an, in particular three-phase, rectifier 54, while the second semiconductor assembly 6 is configured as an, in particular three-phase, inverter 56. The third semiconductor assembly 8 is configured as a monitoring device 58, e.g. a DC-link voltage, in particular as a brake chopper. The inverter 56 comprises switchable semiconductor elements such as transistors, in particular IGBTs, while diodes are used in the rectifier. A substrate surface of the inverter 56 is at least 1.5-times, in particular 2-times, as large as a substrate surface of the rectifier 54 or of the monitoring device 58. The dielectric material layer 32 of the inverter 56 is made of aluminum nitride, while the dielectric material layers 30, 34 of the rectifier 54 and of the monitoring device 58 are made of less expensive aluminum oxide. The further design of the semiconductor module 2 in FIG. 4 corresponds to the design in FIG. 3.

FIG. 5 shows a schematic representation of a power converter 60 having a semiconductor module 2. The power converter 60 can comprise more than one semiconductor module 2.

In summary, the Invention relates to a semiconductor module 2 having at least a first semiconductor assembly 4, a second semiconductor assembly 6 and a common heat sink 14, wherein the heat sink 14 is configured such that a cooling fluid is conducted in a cooling-fluid flow direction 18, wherein the semiconductor assemblies 4, 6 are arranged on a surface 12 of the heat sink 14, wherein the semiconductor assemblies 4, 6 each have a substrate 22, 24, and on each of said substrates 22, 24 at least one semiconductor element 28 is connected, in particular in a material-bonded manner, wherein the substrates 22, 24 each comprise a dielectric material layer 30, 32. In order to achieve greater reliability, it is proposed that a second dielectric material layer 32 of the second semiconductor assembly 6 differs, at least in respect of its thermal conductivity, from a first dielectric material layer 30 of the first semiconductor assembly 4.

1.-16. (canceled)

17. A semiconductor module, comprising:
a heat sink configured to conduct a cooling fluid in a cooling-fluid flow direction;
a first semiconductor assembly arranged on a surface of the heat sink, said first semiconductor assembly comprising a first substrate comprising a first dielectric material layer, and a first semiconductor element connected to the first substrate; and
a second semiconductor assembly arranged on the surface of the heat sink and closest to a downstream end of the heat sink, said second semiconductor assembly comprising a second substrate comprising a second dielectric material layer, and a second semiconductor element connected to the second substrate, said second dielectric material layer having a thermal conductivity which is higher than a thermal conductivity of the first dielectric material layer.

18. The semiconductor module of claim 17, wherein the first semiconductor element of the first semiconductor assembly is connected to the first substrate of the first semiconductor assembly in a material-bonded manner, and wherein the second semiconductor element of the second semiconductor assembly is connected to the second substrate of the second semiconductor assembly in a material-bonded manner.

19. The semiconductor module of claim 17, further comprising a third semiconductor assembly arranged between the first semiconductor assembly and the second semiconductor assembly, said third semiconductor assembly comprising a third substrate comprising a third dielectric material layer, and a third semiconductor element connected to the third substrate, said third dielectric material layer having a thermal conductivity which differs from a thermal conductivity of the first dielectric material layer and/or the second dielectric material layer.

20. The semiconductor module of claim 19, wherein the third semiconductor element of the third semiconductor assembly is connected to the third substrate of the third semiconductor assembly in a material-bonded manner.

21. The semiconductor module of claim 19, wherein the thermal conductivity of the second dielectric material layer is higher than the thermal conductivity of the first dielectric material layer and/or the third dielectric material layer.

22. The semiconductor module of claim 19, wherein the first, second and third semiconductor assemblies are arranged in a staggered pattern along an axis on the surface of the heat sink, with the cooling-fluid flow direction extending substantially along the axis.

23. The semiconductor module of claim 19, wherein the second semiconductor assembly has a substrate surface which is at least 20% larger, in particular at least 50% larger, than a substrate surface of a further one of the first and third semiconductor assemblies arranged on the surface of the heat sink.

24. The semiconductor module of claim 17, wherein the second semiconductor assembly is configured as at least a part of an inverter.

25. The semiconductor module of claim 19, wherein the first, second and third substrates are each directly connected in a material-bonded manner to the surface of the heat sink via a connecting layer.

26. The semiconductor module of claim 17, wherein the first dielectric material layer of the first substrate contains aluminum oxide and the second dielectric material layer of the second substrate contains aluminum nitride,

27. The semiconductor module of claim 17, further comprising a first connecting layer designed to connect the first substrate, and a second connecting layer designed to connect the second substrate, the first connecting layer being thinner than the second connecting layer.

28. The semiconductor module of claim 27, wherein the first connecting layer is made of a first alloy and the second connecting layer is made of a second alloy, with the first alloy having a composition which differs from a composition of the second alloy.

29. The semiconductor module of claim 28, wherein the second alloy has a higher mass fraction of antimony than the first alloy.

30. The semiconductor module of claim 19, wherein the first, second and third substrates each have a thickness d of between 25 μm and 400 μm, in particular 50 μm and 250 μm.

31. The semiconductor module of claim 17, wherein the first and second semiconductor elements are designed as transistors and as diodes connected in anti-parallel.

32. A power converter, comprising the semiconductor module of claim 17.

33. A method for producing the semiconductor module of claim 17, the method comprising:
connecting the first semiconductor element on the first substrate for producing the first semiconductor assembly;
connecting the second semiconductor element on the second substrate for producing the second semiconductor assembly; and
connecting the first and second semiconductor assemblies on the surface of the heat sink.

34. The method of claim 33, wherein the first and second semiconductor elements are connected in a material-bonded manner to the first and second substrates, respectively.

35. The method of claim 33, wherein the first and second semiconductor assemblies are connected in a material-bonded manner on the surface of the heat sink.

36. A computer program product, comprising a computer program embodied on a non-transitory computer readable medium comprising commands which, when the computer program is executed by a computer, cause the computer to simulate an, in particular thermal, mechanical and/or electrical, behavior of the semiconductor module of claim 17.
